(19) United States
(12) Patent Application Publication
(10) Pub. No.: US 2013/0106752 A1
(43) Pub. Date: May 2, 2013

(54) DOUBLE-LAYERED CAPACITIVE TOUCH PANEL AND METHOD FOR MANUFACTURING A DOUBLE-LAYERED CAPACITIVE TOUCH PANEL

(71) Applicant: SENTELIC TECHNOLOGY CO., LTD., Taipei (TW)

(72) Inventors: JAO-CHING LIN, Taipei (TW); LINABEL CHU, Taipei (TW); RONG-SHUN CHANG, Taipei (TW); CHIH-CHIEH YU, New Taipei City (TW)

(73) Assignee: SENTELIC TECHNOLOGY CO., LTD., Taipei (TW)

(21) Appl. No.: 13/662,501

(22) Filed: Oct. 28, 2012

(30) Foreign Application Priority Data
Oct. 28, 2011 (TW) 100139364

(51) Int. Cl. G06F 3/041; H05K 3/12

(52) U.S. Cl. 345/173; 29/846

(57) ABSTRACT

Approach is provided for a double-layered capacitive touch panel, which comprises a printed circuit board, a first electrode layer, an insulating layer and a second electrode layer. The printed circuit board has an insulating substrate and a conductive foil on the insulating substrate, and comprises multiple first conductive holes and multiple second conductive holes. The conductive foil comprises multiple first conductive lines and multiple second conductive lines. The first electrode layer is printed on a second surface of the insulating substrate, comprises multiple first electrode rows, and conducts to the first conductive lines through the first conductive holes. The insulating layer is printed on the first electrode layer and remaining the exposure of the second conductive holes. The second electrode layer is printed on the insulating layer, comprising multiple second electrode rows that are connected to the second conductive lines through the second conductive holes.

### FIELD OF THE INVENTION

Embodiments of the invention relate to touch panel, and more particularly to double-layered capacitive touch panels and methods for manufacturing a double-layered capacitive touch panel.

### BACKGROUND

With reference to FIG. 1, the Taiwan patent No. M378434 has disclosed a two-layered capacitive touch panel that comprises a two-layered printed circuit board (PCB) 10 and an insulating layer 13. The PCB 10 has an upper surface and a lower surface, and comprises multiple first connecting holes 1112 and multiple second connecting holes 1114 that are penetrated a first surface and a second surface of the PCB 10. The upper surface is disposed a first cupper layer to form multiple first electrode rows 12 extended along a first direction and connected to the first connecting holes 1112. The lower surface is disposed a second cupper layer and comprises multiple first conductive wires 11a extended to connect with the first connecting holes 1112 and multiple second conductive wires 11b extended to connect with the second connecting holes 1114. The insulating layer 13 is mounted on the first cupper layer but the second connecting holes 1114 are exposed. Multiple second electrode rows 14 are disposed on the insulating layer 13, perpendicular to the fist electrode rows 12 and extended to connect with the second connecting holes 1114. However, two layers of cupper are necessary to respectively disposed on the both surfaces of the PCB of the two-layered capacitive touch panel and thus increases the manufacturing cost.

With reference to the FIG. 2, the U.S. Pat. No. 6,188,391 titled two-layer capacitive touchpad and method of making same has disclosed another type of double-layered capacitive touch panel that comprises multiple conductive holes 66 penetrated an upper surface and a bottom surface of a double-layered PCB 62 along edges of the PCB 62. The upper surface of the PCB 62 is disposed a cupper layer to form multiple electrodes 68. Partial electrodes 68 are electrical connected to each other by multiple cupper conductive wires 69 that are extended along a first direction and are connected to partial conductive holes 66 to form a first electrode row 63. Other electrodes 68 are extended and passed through the conductive holes 66 and connects to the conductive holes 66 disposed on the other surface. Further, a carbon-inked conductive wire is printed on the other surface and connects to the cupper layer that extended and disposed around the hole to form the double-layered capacitive touch panel 100.

Above-mentioned prior arts not only have to use a PCB with two cupper layers thus increase the manufacturing expense, but also have difficulty to stable and steady fix the cupper layer or other metallic material on the hole due to natural properties of the metal while penetrating the cupper layer or other metallic material through the hole. Thus, the cupper layer or other metallic material might be separated from the holes. Further, the carbon-ink and the independent electrodes are hetero materials and might decrease the stability of the conjunct electrical structure. The manufacturing process is also complex and requires highly precise operation, both have barrier for industrial improvement.

### SOME EXEMPLARY EMBODIMENTS

These and other needs are addressed by the invention, wherein approaches are provided for a double-layered capacitive touch panel structure and its manufacturing method with a reliable electrical coupling ability and lower manufacturing cost.

According to one aspect of an embodiment of the invention, a double-layered capacitive touch panel comprises a printed circuit board, a first electrode layer, an insulating layer and a second electrode layer. The printed circuit board has an insulating substrate and a conductive foil on a first surface of the insulating substrate, and comprises multiple first conductive holes and multiple second conductive holes formed and penetrated two side of the printed circuit board. The conductive foil comprises multiple first conductive lines and multiple second conductive lines extended to the corresponding conductive holes respectively. The first electrode layer is printed on a second surface of the insulating substrate, and comprises multiple first electrode rows aligned in the first direction, and are extend to the first conductive holes that electrical conducts to the first conductive lines through the first conductive holes.

The insulating layer being printed on the first electrode layer and remaining the exposure of the second conductive holes. The second electrode layer is printed on the insulating layer and comprises multiple second electrode rows. The second electrode rows are aligned in the second direction and extend to the second conductive holes which are electrically connected to the corresponding second conductive lines through the exposed second conductive holes.

According to another aspect of an embodiment of the invention, a method for manufacturing a double-layered capacitive touch panel comprises acts of obtaining a printed circuit board that has a insulating substrate and a conductive foil formed on a first surface of the insulating substrate; forming multiple first and second conductive holes penetrated two sides of the printed circuit board; forming multiple first and second conductive lines respectively from the conductive foil corresponded to the first and second conductive holes; forming a first electrode layer by the screen-printing process on a second surface of the insulating substrate, which creates multiple first electrode rows along a first direction that are electrically connected to the first conductive lines through the corresponding first conductive holes; forming an insulating layer by the screen-printing process which covers the first electrode rows and the first conductive holes, wherein the second conductive holes are remain exposed; and forming a second electrode layer by the screen-printing process on the insulating substrate, which creates multiple second electrode rows along a second direction that are electrically connected to the second conductive lines through the corresponding second conductive holes.

According to other aspect of an embodiment of the invention, a double-layered capacitive touch panel comprises a printed circuit board, a third electrode layer, an insulating layer and multiple third conductive lines. The printed circuit board has an insulating substrate and a conductive foil on a first surface of the insulating substrate, and comprises multiple first conductive holes and multiple second conductive holes formed and penetrated two side of the printed circuit board. The conductive foil comprises multiple first conductive lines and multiple second conductive lines extended to the corresponding conductive holes respectively. The third electrode layer is printed on the second surface of the insulating substrate, and comprises multiple third electrode rows and multiple independent electrodes. The third electrode rows are electrically connected to the corresponding first conductive lines through the first conductive holes, and the independent electrodes are placed with the corresponding third electrode rows in an interlaced fashion along the second direction. The insulating layer is printed on the third electrode layer and remains the exposure of the second conductive holes. The third conductive lines are formed on the insulating layer electrically connected to the independent electrodes along the second direction that from multiple fourth electrode rows perpendicular to the third electrode rows have electrically conduct with the second conductive lines through the second conductive holes.

According to yet another aspect of an embodiment of the invention, a method for manufacturing a double-layered capacitive touch panel comprises acts of obtaining a printed circuit board that has a insulating substrate and a conductive foil formed on a first surface of the insulating substrate; forming multiple first and second conductive holes penetrated two sides of the printed circuit board; forming multiple first and second conductive lines respectively from the conductive foil corresponded to the first and second conductive holes; forming a third electrode layer by the screen-printing process on a second surface of the insulating substrate, which creates multiple third electrode rows and multiple independent electrodes, wherein the third electrode rows are aligned in a first direction and connects to the first conductive lines through the first conductive holes, and the independent electrodes are aligned in a second direction and corresponds the third electrode rows in an interlaced fashion; forming an insulating layer on the third electrode layer by the screen-printing process that covers the third electrode rows and the first conductive holes, and remains the independent electrodes and the second conductive holes exposed; and forming multiple third conductive lines on the insulating layer by the screen-printing process which electrically connect to the independent electrodes along the second direction that from multiple fourth electrode rows perpendicular to the third electrode rows having electrically connects with the second conductive lines through the second conductive holes.

In embodiments, the electrode layers and the third conductive lines may be made of a conductive material that is selected from a group consisting of a graphite and a silver gel.

Accordingly, the printed circuit board used in the embodiments of the present invention reduces an additional layer of copper foil to the known technique, and thus reduces its cost on manufacturing. Further, since the first and third electrode rows, and the second and fourth electrode rows are using conductive material with same characteristic (e.g. graphite, silver gel or the mixture of both), the structure of the electrical coupling of the electrodes can be more stable and the has simpler manufacturing process.

Still other aspects, features and advantages of the invention are readily apparent from the following detailed description, simply by illustrating a number of particular embodiments and implementations, including the best mode contemplated for carrying out the invention. The invention is also capable of other and different embodiments, and its several details can be modified in various obvious respects, all without departing from the spirit and scope of the invention. Accordingly, the drawings and description are to be regarded as illustrative, and not as restrictive.

### BRIEF DESCRIPTION OF THE DRAWINGS

The invention is illustrated by way of example, and not by way of limitation, in the figures of the accompanying drawings in which like reference numerals refer to similar elements and in which:

FIG. 1 is a cross-sectional view of a conventional two-layered capacitive touch panel;

FIG. 2 is a cross-sectional view of another conventional two-layered capacitive touch panel;

FIG. 3 is a flow chart of a method for manufacturing a double-layered capacitive touch panel in accordance with an embodiment of the present invention;

FIG. 4 is an exemplary diagram of a printed circuit board of a double-layered capacitive touch panel in accordance with an embodiment of the present invention;

FIG. 5 is an exemplary diagram of the printed circuit board of FIG. 4 having multiple first conductive holes and multiple second conductive holes penetrated two sides of the printed circuit board;

FIG. 6 is an exemplary diagram of multiple first and second conductive lines respectively from the conductive foil corresponded to the first and second conductive holes in accordance with an embodiment of the present invention;

FIG. 7 is an exemplary diagram of a first electrode layer printed on another side of the printed circuit board in accordance with an embodiment of the present invention;

FIG. 8 is an exemplary diagram of an insulating layer printed on the first electrode layer and remains the second conductive holes exposed in accordance with an embodiment of the present invention;

FIG. 9 is an exemplary diagram of a second electrode layer printed on the insulating layer in accordance with an embodiment of the present invention;

FIG. 10 is a cross-sectional view along the A-A line in the FIG. 9;

FIG. 11 is a flow chart of a method for manufacturing a double-layered capacitive touch panel in accordance with another embodiment of the present invention;

FIG. 12 is an exemplary diagram of a third electrode layer printed on the other side of the printed circuit board having multiple third electrode rows and multiple independent electrodes in accordance with another embodiment of the present invention;

FIG. 13 is an exemplary diagram of an insulating layer printed on the third electrode layer and remains the independent electrodes exposed in accordance with another embodiment of the present invention;

FIG. 14 is an exemplary diagram of multiple third conductive lines printed on the insulating layer and electrically coupled with the independent electrodes to form multiple fourth electrode rows in accordance with another embodiment of the present invention;

FIG. 15 is a cross-sectional view along the B-B line in the FIG. 14;

FIG. 16 is an exemplary diagram of an insulating layer printed on the third electrode layer and having multiple through hole communicated with the independent electrodes and the second conductive holes in accordance with another embodiment of the present invention;

FIG. 17 is an exemplary diagram of multiple third conductive lines electrically connected to the independent electrodes through the through holes of FIG. 16; and

FIG. 18 is a cross-sectional view along the C-C line in the FIG. 17.

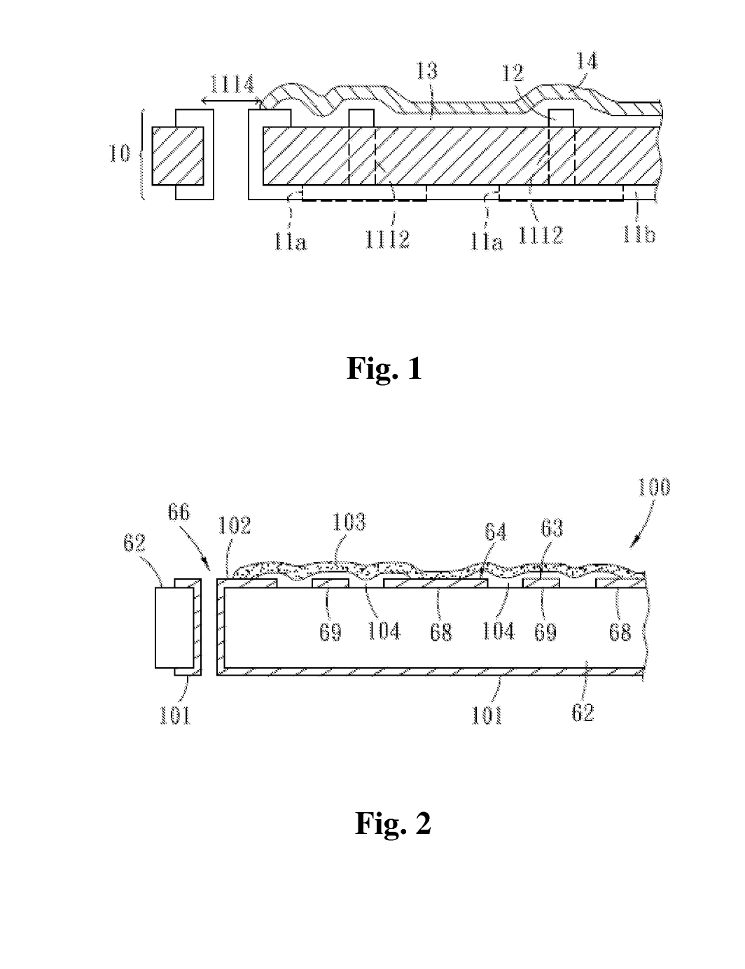

### DESCRIPTION OF THE PREFERRED EMBODIMENT

In the following description, for purposes of explanation, numerous specific details are set forth in order to provide a thorough understanding of the embodiment of the invention. It is apparent, however, to one skilled in the art that the present invention may be practiced without these specific details or with an equivalent arrangement. Same element in various embodiments of the present invention may use same numbering in different illustrated figures.

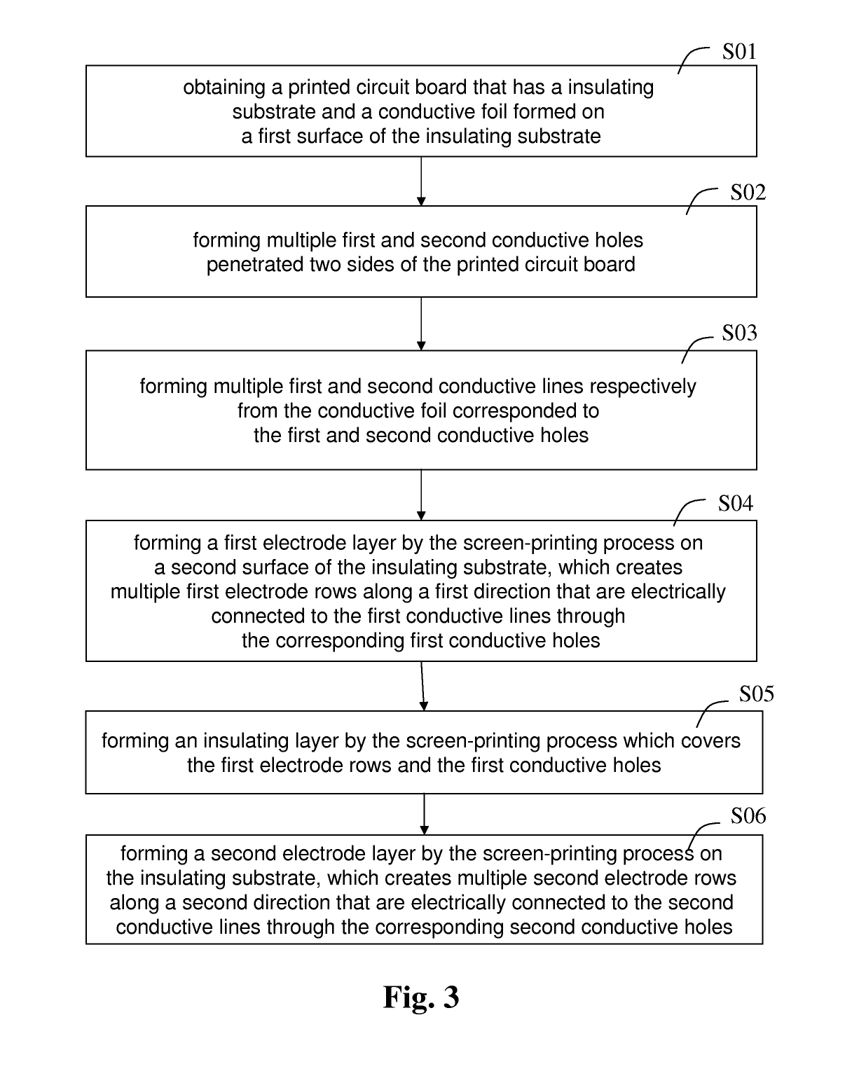

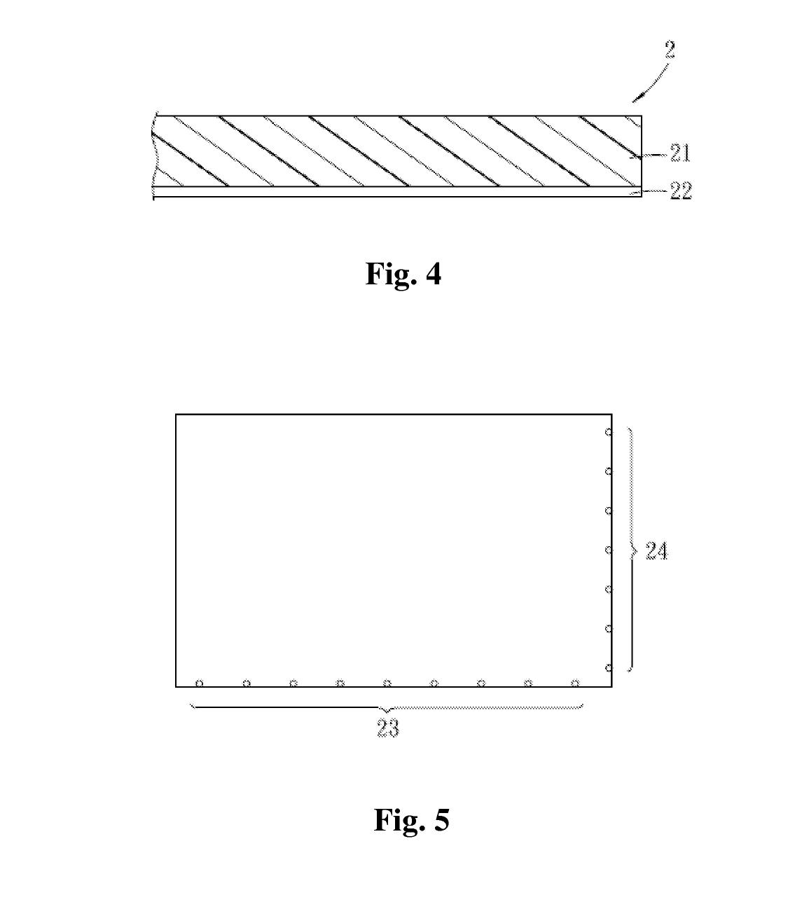

With reference to FIGS. 3 to 10, embodiments of the double-layered capacitive touch panel and method for manufacturing the double-layered capacitive touch panel are disclosed. FIG. 3 is a flow chart of the method for manufacturing the double-layered capacitive touch panel, and FIGS. 4 to 10 are exemplary diagrams of the double-layered capacitive touch panel to the corresponding steps of FIG. 3.

As shown FIG. 3, the method for manufacturing a double-layered capacitive touch panel comprises acts of S01 obtaining a printed circuit board (PCB) that has a insulating substrate and a conductive foil formed on a first surface of the insulating substrate, S02 forming multiple first and second conductive holes penetrated two sides of the printed circuit board, S03 forming multiple first and second conductive lines respectively from the conductive foil corresponded to the first and second conductive holes, S04 forming a first electrode layer by the screen-printing process on a second surface of the insulating substrate, which creates multiple first electrode rows along a first direction that are electrically connected to the first conductive lines through the corresponding first conductive holes, S05 forming an insulating layer by the screen-printing process which covers the first electrode rows and the first conductive holes, and S06 forming a second electrode layer by the screen-printing process on the insulating substrate, which creates multiple second electrode rows along a second direction that are electrically connected to the second conductive lines through the corresponding second conductive holes.

With reference to FIGS. 3 and 4, in step S01, the printed circuit board 2 comprises the insulating substrate 21 and the conductive foil 22 on the first surface of the insulating substrate 21. In this embodiment, the conductive foil 22 is made of copper.

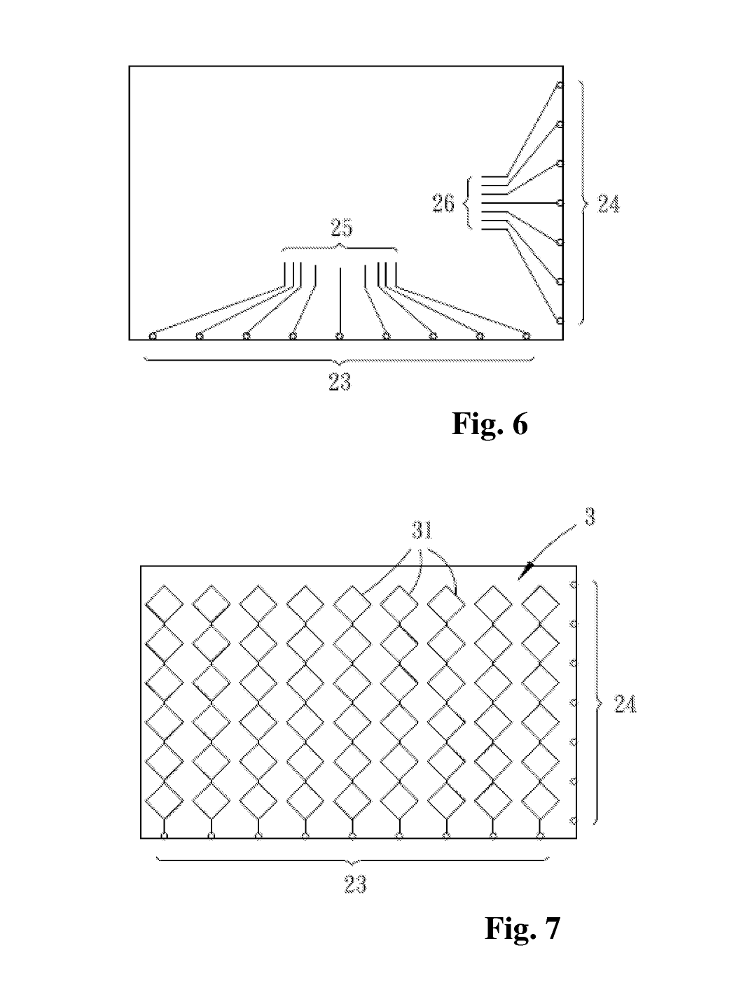

With reference to FIGS. 3, 5 and 6, in step S02 and S03, multiple first conductive holes 23 and multiple second conductive holes 24, as shown in FIG. 5, are formed and penetrated two side of the printed circuit board 2. Multiple first conductive lines 25 and multiple second conductive lines 26, as shown in FIG. 6, are formed to the corresponding conductive holes 23, 24 respectively. In this embodiment, the conductive lines 25, 26 are formed by implementing the etching process to the conductive foil 22.

With reference to FIGS. 3 and 7, in step S04, the first electrode layer 3 is formed on the second surface of the insulating substrate 21 that is opposite to the first surface by implementing the screen-printing process. The first electrode layer 3, as shown in FIG. 7, comprises multiple first electrode rows 31. The first electrode rows 31 are aligned in the first direction (e.g. Y-axis), and extends to the first conductive holes 23. The first electrode rows 31 are then electrically connected to the corresponding first conductive lines 25 through the first conductive holes 23. In one embodiment, the first electrode row 31 is made of a conductive material (also known as conductive ink) selected from a group consisting of graphite and silver gel. The first electrode layer 3 is then dried after the conductive material is introduced and has conducted with the first conductive lines 25 through the first conductive holes 23. The opening size of the first conductive holes 23 are configured large enough for letting the conductive material in and create electrical connections with the first conductive lines 25.

In order to make the introduction of the conductive material easier into the first conductive holes 23, the first conductive hole 23 may be shaped in a funnel that has a larger opening on the top.

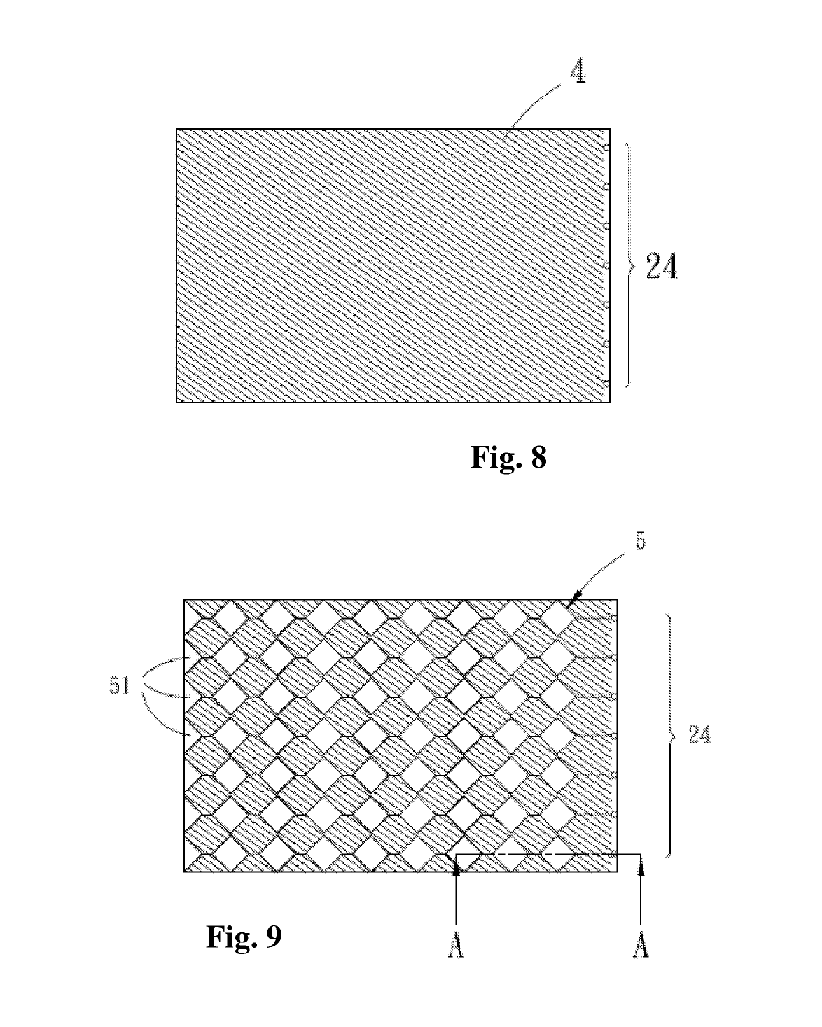

With reference to FIGS. 3 and 8, in step S05, the insulating layer 4 is coated on the first electrode layer 3 using the screen-printing process. As shown in FIG. 8, the first electrode rows 31 and the first conductive holes 23 are covered by the insulating layer 4, and the second conductive holes 24 remains exposed. The insulating layer 4 is then dried and formed.

With reference to FIGS. 3 and 9, in step S06, the second electrode layer 5 is formed on the insulating layer 4 using the screen-printing process. As shown in FIG. 9, the second electrode layer 5 comprises multiple second electrode rows 51. The second electrode rows 51 are aligned in the second direction (e.g. X-axis) that is perpendicular to the first direction, and extends to the second conductive holes 24. The second electrode rows 51 are then electrically connected to the corresponding second conductive lines 26 through the exposed second conductive holes 24. In one embodiment, the second electrode row 51 is made of a conductive material (also know as conductive ink) selected from a group consisting of graphite and silver gel. The first electrode layer 3 is then dried after the conductive material is introduced and has conducted with the first conductive lines 25 through the first conductive holes 23. The second electrode layer 5 is then dried after the conductive material is introduced and has conducted with the second conductive lines 26 through the second conductive holes 24. The opening size of the second conductive holes 24 are configured large enough for letting the conductive material in and create electrical connections with the second conductive lines 26.

In order to make the introduction of the conductive material easier into the second conductive holes 24, the second conductive hole 24 may be shaped in a funnel that has a larger opening on the top.

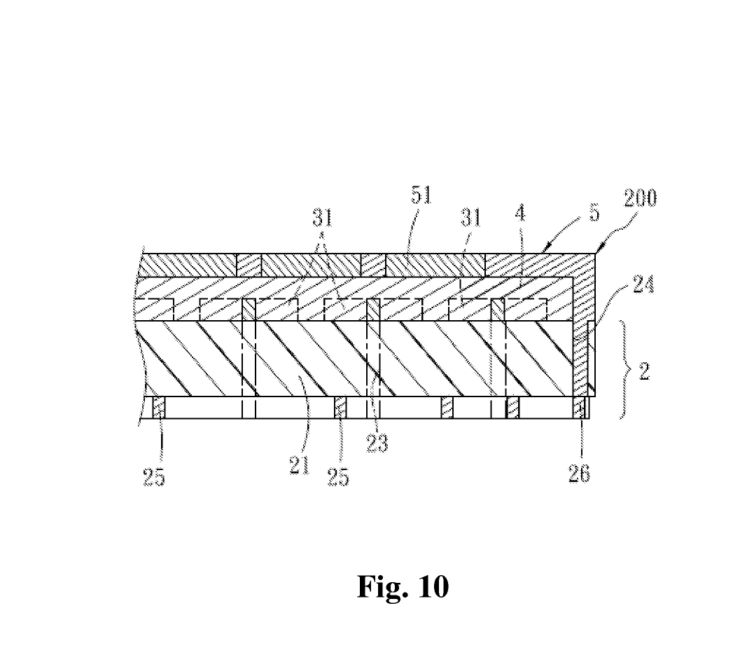

Therefore, with reference to FIGS. 3 and 10, the double-layered capacitive touch panel 200 can be made through the steps S01 to S06, which comprises a printed circuit board 2, a first electrode layer 3, an insulating layer 4 and a second electrode layer 5. As shown in FIG. 10, the printed circuit board 2 has an insulating substrate 21 and a conductive foil 22 mounted on a first surface (i.e. bottom surface) of the insulating substrate 21. The printed circuit board 2 further comprises multiple first conductive holes 23 and multiple second conductive holes 24 are formed and penetrated two side of the printed circuit board 2. The conductive foil 22 further comprises multiple first conductive lines 25 and multiple second conductive lines 26 are formed to the corresponding conductive holes 23, 24 respectively.

The first electrode layer 3 is printed on the second surface (i.e. top surface) of the insulating substrate 21, and comprises multiple first electrode rows 31. The first electrode rows 31 are aligned in the first direction, and extend to the first conductive holes 23, which make electrical conducted with first conductive lines 25 through the first conductive holes 23.

The insulating layer 4 is printed on the first electrode layer 3, and is configured for covering the first electrode rows 31 and the first conductive holes 23 and remaining the second conductive holes 24 exposed from it.

The second electrode layer 5 is printed on the insulating layer and comprises multiple second electrode rows 51. The second electrode rows 51 are aligned in the second direction that is perpendicular to the first direction, and extends to the second conductive holes 24. The second electrode rows 51 are then electrically connected to the corresponding second conductive lines 26 through the exposed second conductive holes 24. In this manner, the first conductive lines 25 and the second conductive lines 26 is configured for electrical connections to a electronic component such as a controller or a control circuit (not shown in figures), which may be used transmitting an induced touching signal to the electronic component that is detected by the double-layered capacitive touch panel.

With reference to FIGS. 4-6, and 11-14, FIG. 11 illustrates manufacturing method of producing the double-layered capacitive touch panel in accordance with another embedment of the present invention.

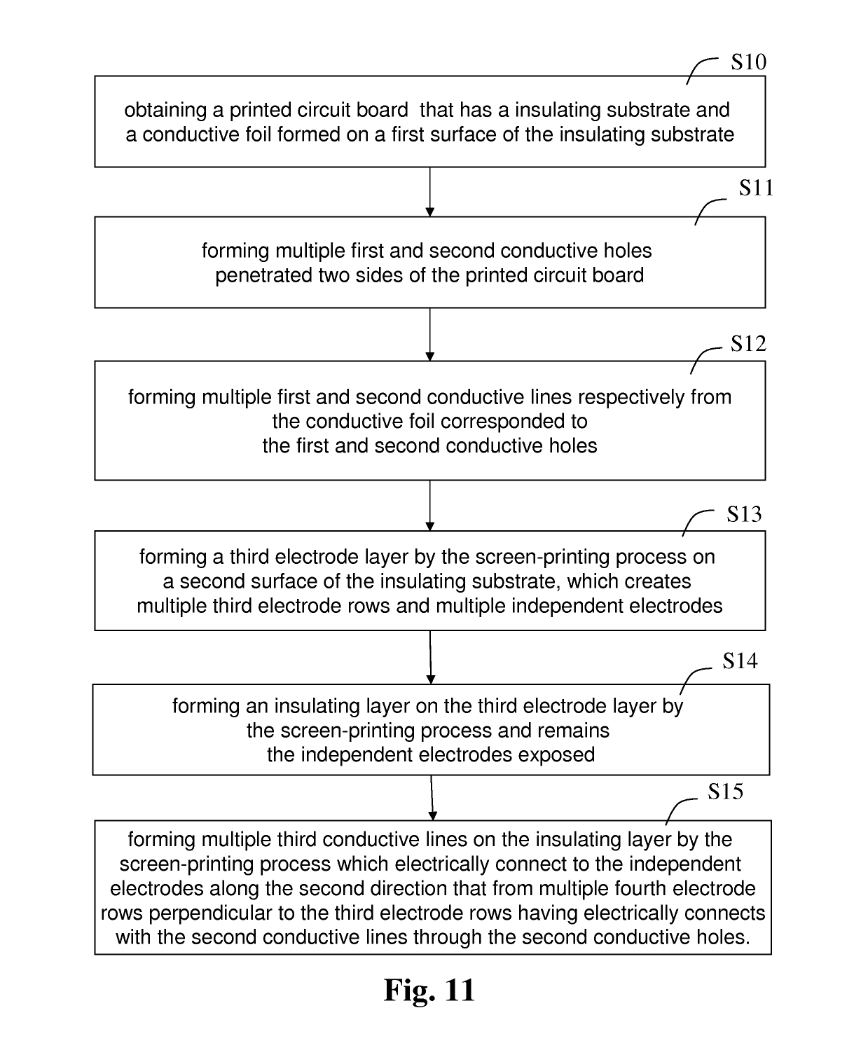

As shown in FIG. 11, the method for manufacturing a double-layered capacitive touch panel comprises acts of S10 obtaining a printed circuit board (PCB) that has a insulating substrate and a conductive foil formed on a first surface of the insulating substrate, S11 forming multiple first and second conductive holes penetrated two sides of the printed circuit board, S12 forming multiple first and second conductive lines respectively from the conductive foil corresponded to the first and second conductive holes, S13 forming a third electrode layer by the screen-printing process on a second surface of the insulating substrate, which creates multiple third electrode rows and multiple independent electrodes, S14 forming an insulating layer on the third electrode layer by the screen-printing process and remains the independent electrodes exposed, and S15 forming multiple third conductive lines on the insulating layer by the screen-printing process which electrically connect to the independent electrodes along the second direction that from multiple fourth electrode rows perpendicular to the third electrode rows having electrically connects with the second conductive lines through the second conductive holes.

With reference to FIGS. 4-6 and 11, the steps S10-S12 are similar to the steps S01-S03 in FIG. 3, which a printed circuit board 2 having a single-layered conductive foil 22 is provided as shown in FIG. 4. The printed circuit board 2, as shown in FIG. 5, further comprises multiple first conductive holes 23 and multiple second conductive holes 24 formed and penetrated two side of the printed circuit board 2. Multiple first conductive lines 25 and multiple second conductive lines 26, as shown in FIG. 6, are formed from the conductive foil 22 on the first surface of the insulating layer 21, and extend to the corresponding conductive holes 23, 24 respectively.

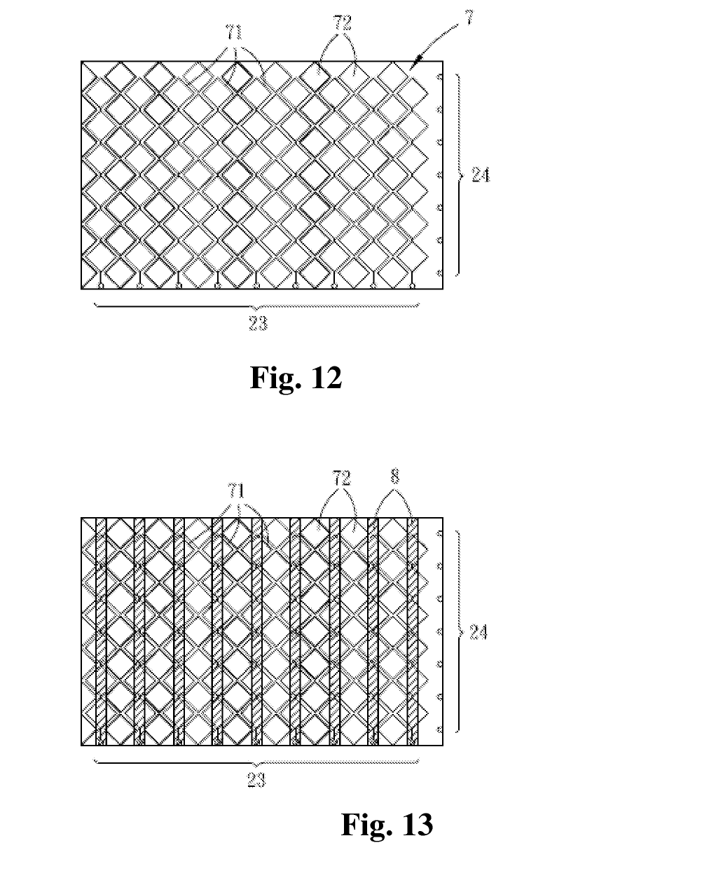

With reference to FIGS. 11 and 12, in step S13, the third electrode layer 7 is formed on the second surface of the insulating substrate 21 where is not coated with the conductive foil 22. As shown in FIG. 12, the third electrode layer 7 comprises multiple third electrode rows 71 and multiple independent electrodes 72.

The third electrode rows 71 are aligned in a first direction and extend to the first conductive holes 23. The third electrode rows 71 are then electrically connected to the corresponding first conductive lines 25 through the first conductive holes 23. The independent electrodes 72 are placed but not contacted with the corresponding third electrode rows 71 in an interlaced fashion, and are expansively duplicated along the second direction that is perpendicular to the first direction. In one embodiment, the third electrode rows 71 and the independent electrodes 72 are made of a conductive material (also known as conductive ink) printed on the insulating layer 21, which is selected from a group consisting of graphite and silver gel. The third electrode layer 7 is then dried after the conductive material is introduced and has conducted with the first conductive lines 25 through the first conductive holes 23. The opening size of the first conductive holes 23 are configured large enough for letting the conductive material in and create electrical connections with the first conductive lines 25.

In order to make the introduction of the conductive material easier into the first conductive holes 23, the first conductive hole 23 may be shaped in a funnel that has a larger opening on the top.

With reference to FIGS. 11 and 13, in step S14, the insulating layer 8 is printed on the third electrode layer 7 using screen-printing process. The insulating layer 8 is coated on the third electrode layer 7 and the first conductive holes 23. As shown in FIG. 13, the insulating layer 8 is then dries on the third electrode layer 7 may be partially or completely covered on the third electrode rows 71, and remains the exposure of the independent electrodes 72 and the second conductive holes 24.

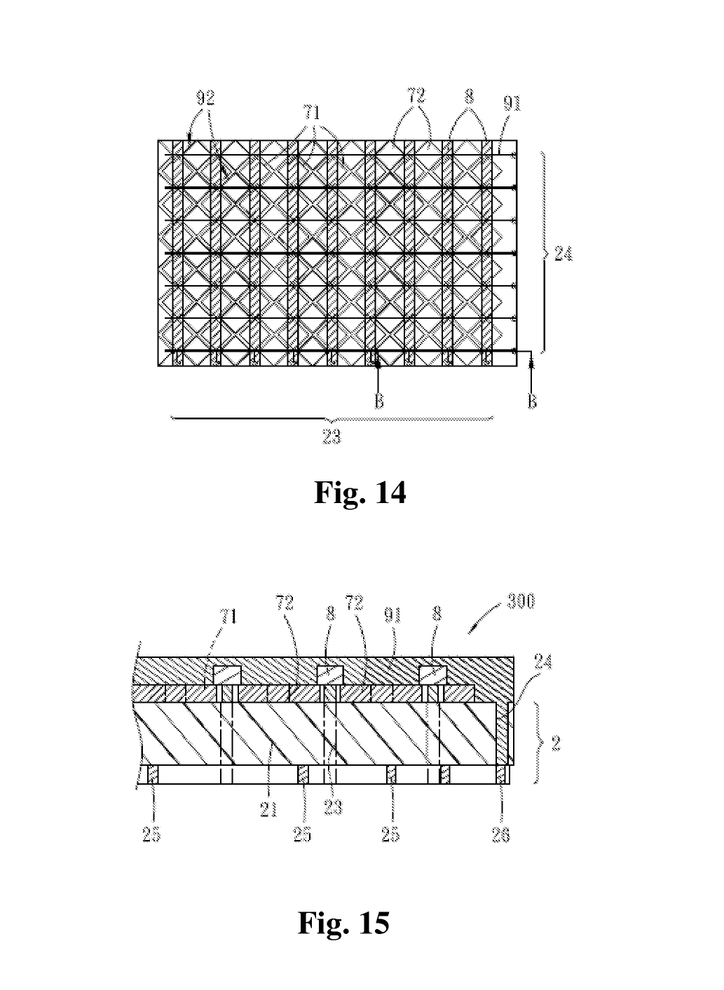

With reference to FIGS. 11 and 14, in step S15, The third conductive lines 91 are printed along the second direction on the insulating layer 8 using screen-printing process. As shown in FIG. 14, the third conductive lines 91 are electrically connected to the exposed independent electrodes 72 respectively along the second direction. The coupled third conductive lines 91 and the independent electrodes 72 form the fourth electrode rows 92 aligned along the second direction that is perpendicular to the third electrode rows 71, and the third conductive lines 91 further extend to connect electrically to the corresponding second conductive lines 26 through the second conductive holes 24. In one embodiment, the third conductive lines 91 are made of a conductive material (also known as conductive ink) selected from a group consisting of graphite and silver gel. The third conductive lines 91 are dried after the third conductive lines have conducted with the second conductive lines 26.

In order to make the introduction of the conductive material easier into the second conductive holes 24, the second conductive hole 24 may be shaped in a funnel that has a larger opening on the top.

Therefore, with reference to FIGS. 11 and 15, the double-layered capacitive touch panel 300 can be made through the steps S10 to S15, which comprises a printed circuit board 2, a third electrode layer 7, an insulating layer 8 and multiple third conductive lines 91. As shown in FIG. 10, the printed circuit board 2 has an insulating substrate 21 and a conductive foil 22 mounted on a first surface (i.e. bottom surface) of the insulating substrate 21. The printed circuit board 2 further comprises multiple first conductive holes 23 and multiple second conductive holes 24 are formed and penetrated two side of the printed circuit board 2. The conductive foil 22 further comprises multiple first conductive lines 25 and multiple second conductive lines 26 are formed to the corresponding conductive holes 23, 24 respectively.

The third electrode layer 7 is printed on the second surface (i.e. top surface) of the insulating substrate 21, and comprises multiple third electrode rows 71 and multiple independent electrodes 72. The third electrode rows 71 are aligned in a first direction and extend to the first conductive holes 23. The third electrode rows 71 are then electrically connected to the corresponding first conductive lines 25 through the first conductive holes 23. The independent electrodes 72 are placed but not contacted with the corresponding third electrode rows 71 in an interlaced fashion, and are expansively duplicated along the second direction that is perpendicular to the first direction.

The insulating layer 8 is printed on the third electrode layer 7, which covers the third electrode layer 7 and the first conductive holes 23 of the electrode layer 7, and remains the exposure of the independent electrodes 72 and the second conductive holes 24. The third conductive lines 91 are electrically connected to the exposed independent electrodes 72 respectively along the second direction on the insulating layer 8, which from multiple fourth electrode rows 92 aligned along the second direction that is perpendicular to the third electrode rows 71, and the third conductive lines 91 further extend to connect electrically to the corresponding second conductive lines 26 through the second conductive holes 24.

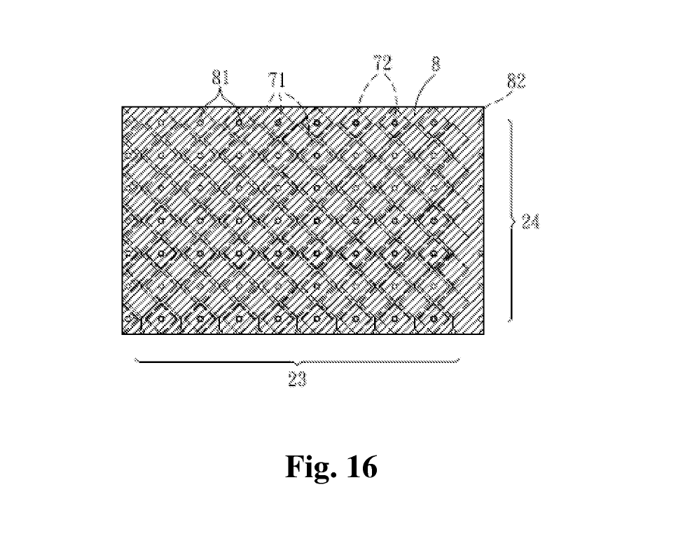

With reference to FIGS. 16-18, a double-layered capacitive touch 400 in accordance with yet another embodiment of the present invention is disclosed. In this embodiment, the insulating layer 8 covers completely on the third electrode layer 7, and the insulating layer 8 comprises multiple through holes 81, 82. The first through holes 81 are configured to communicate with the independent electrodes 72, and the second through holes 82 are configured to communicate with the second conductive holes 24.

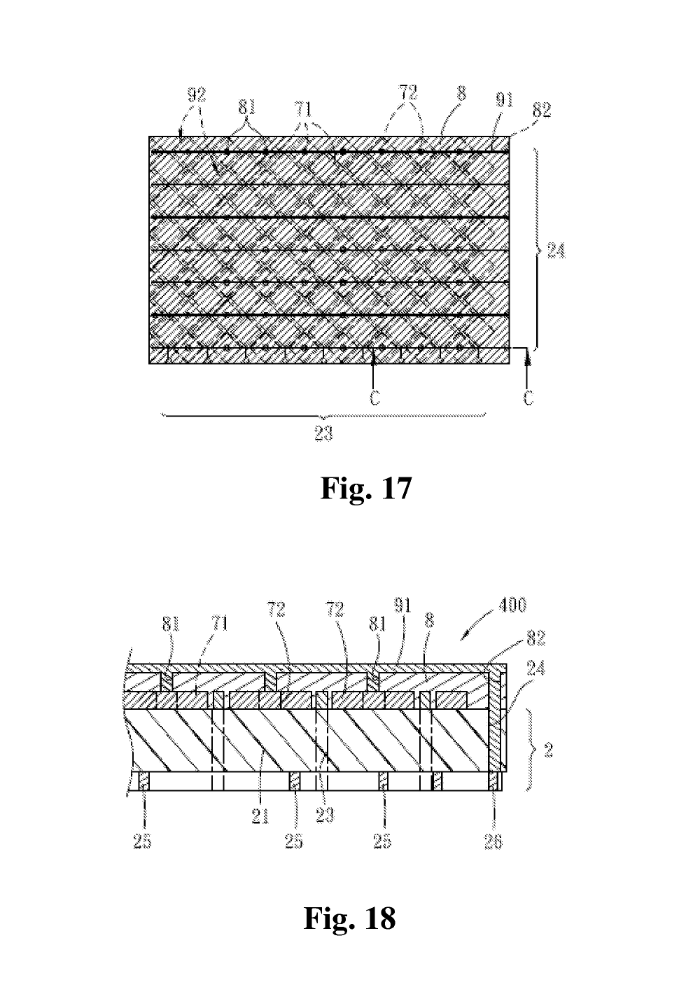

As shown in FIG. 17, the third conductive lines 91 are printed on the insulating layer 8 along the second direction. Each third conductive lines 91 is electrically connected to the independent electrodes 72 and the second conductive hole 24 through the through holes 81, 82. In this manner, multiple fourth electrode rows 92 are formed aligned along the second directions which are perpendicular to the third electrode rows 71.

Accordingly, through various embodiments above-disclosed, the printed circuit board used in the embodiments of the present invention reduces an additional layer of copper foil to the known technique, and thus reduces its cost on manufacturing. Further, since the first and third electrode rows 31, 71, and the second and fourth electrode rows 51, 92 are using conductive material with same characteristic (e.g. graphite, silver gel or the mixture of both), the structure of the electrical coupling of the electrodes can be more stable and the has simpler manufacturing process.

While the invention has been described in connection with a number of embodiments and implementations, the invention is not so limited but covers various obvious modifications and equivalent arrangements, which fall within the purview of the appended claims. Although features of the invention are expressed in certain combinations among the claims, it is contemplated that these features can be arranged in any combination and order.

What is claimed is:

1. A double-layered capacitive touch panel comprising:
a printed circuit board having an insulating substrate and a conductive foil on a first surface of the insulating substrate, and comprising multiple first conductive holes and multiple second conductive holes formed and penetrated two side of the printed circuit board, wherein the conductive foil comprises multiple first conductive lines and multiple second conductive lines extended to the corresponding conductive holes respectively;
a first electrode layer being printed on a second surface of the insulating substrate, and comprising multiple first electrode rows aligned in the first direction, and being extend to the first conductive holes that electrical conducts to the first conductive lines through the first conductive holes;
an insulating layer being printed on the first electrode layer and remaining the exposure of the second conductive holes; and
a second electrode layer being printed on the insulating layer and comprising multiple second electrode rows, and the second electrode rows being aligned in the second direction and extending to the second conductive holes which are electrically connected to the corresponding second conductive lines through the exposed second conductive holes.

2. The double-layered capacitive touch panel as claimed in claim 1, wherein
the first electrode layer is formed by printing a conductive material on the second surface of the insulating substrate using the screen-printing process; and
the second electrode layer is formed by printing the conductive material on the insulating layer suing the screen-printing process.

3. The capacitive touch panel as claimed in claim 2, wherein the conductive material is selected from a group consisting a graphite and a silver gel.

4. A double-layered capacitive touch panel comprising:
a printed circuit board having an insulating substrate and a conductive foil on a first surface of the insulating substrate, and comprising multiple first conductive holes and multiple second conductive holes formed and penetrated two side of the printed circuit board, wherein the conductive foil comprises multiple first conductive lines and multiple second conductive lines extended to the corresponding conductive holes respectively;
a third electrode layer being printed on the second surface of the insulating substrate, and comprising multiple third electrode rows and multiple independent electrodes, wherein the third electrode rows are electrically connected to the corresponding first conductive lines through the first conductive holes, and the independent electrodes are placed with the corresponding third electrode rows in an interlaced fashion along the second direction;
an insulating layer being printed on the third electrode layer and remaining the exposure of the second conductive holes; and
multiple third conductive lines being formed on the insulating layer electrically connected to the independent electrodes along the second direction that from multiple fourth electrode rows perpendicular to the third electrode rows having electrically conduct with the second conductive lines through the second conductive holes.

5. The double-layered capacitive touch panel as claimed in claim 4, wherein
the third electrode layer is formed by printing a conductive material on the second surface of the insulating substrate using the screen-printing process; and
the third conductive lines are formed by printing the conductive material on the insulating layer suing the screen-printing process.

6. The capacitive touch panel as claimed in claim 5, wherein the conductive material is selected from a group consisting a graphite and a silver gel.

7. A method for manufacturing a double-layered capacitive touch panel, comprising:
obtaining a printed circuit board that has a insulating substrate and a conductive foil formed on a first surface of the insulating substrate;
forming multiple first and second conductive holes penetrated two sides of the printed circuit board;
forming multiple first and second conductive lines respectively from the conductive foil corresponded to the first and second conductive holes;
forming a first electrode layer by the screen-printing process on a second surface of the insulating substrate, which creates multiple first electrode rows along a first direction that are electrically connected to the first conductive lines through the corresponding first conductive holes;
forming an insulating layer by the screen-printing process which covers the first electrode rows and the first conductive holes, wherein the second conductive holes are remain exposed; and
forming a second electrode layer by the screen-printing process on the insulating substrate, which creates multiple second electrode rows along a second direction that are electrically connected to the second conductive lines through the corresponding second conductive holes.

8. The method as claimed in claim 7, wherein the first and the second electrode layers are made of a conductive material that is selected from a group consisting of a graphite and a silver gel.

9. The method as claimed in claim 8, wherein the first electrode layer is then dried after the conductive material is introduced and has conducted with the first conductive lines through the first conductive holes.

10. The method as claimed in claim 8, wherein the insulating layer is dried after the being printed on the first electrode layer.

11. The method as claimed in claim 8, wherein the second electrode layer is then dried after the conductive material is introduced and has conducted with the second conductive lines through the second conductive holes.

12. A method for manufacturing a double-layered capacitive touch panel, comprising:
obtaining a printed circuit board that has a insulating substrate and a conductive foil formed on a first surface of the insulating substrate;
forming multiple first and second conductive holes penetrated two sides of the printed circuit board;
forming multiple first and second conductive lines respectively from the conductive foil corresponded to the first and second conductive holes;
forming a third electrode layer by the screen-printing process on a second surface of the insulating substrate, which creates multiple third electrode rows and multiple independent electrodes, wherein the third electrode rows are aligned in a first direction and connects to the first conductive lines through the first conductive holes, and the independent electrodes are aligned in a second direction and corresponds the third electrode rows in an interlaced fashion;
forming an insulating layer on the third electrode layer by the screen-printing process that covers the third electrode rows and the first conductive holes, and remains the independent electrodes and the second conductive holes exposed; and
forming multiple third conductive lines on the insulating layer by the screen-printing process which electrically connect to the independent electrodes along the second direction that from multiple fourth electrode rows perpendicular to the third electrode rows having electrically connects with the second conductive lines through the second conductive holes.

13. The method as claimed in claim 12, wherein the exposure of the independent electrodes and the second conductive holes whereby forming multiple through holes on the insulating layer communicated with the independent electrodes and the second conductive holes respectively.

14. The method as claimed in claim 12, wherein the third conductive lines are printed on the insulating layer along the second direction, and the third conductive lines are electrically connected to the independent electrodes and the second conductive hole through the through holes that form multiple fourth electrode rows.

15. The method as claimed in claim 12, wherein the third electrode later and the third conductive lines are made of a conductive material that is selected from a group consisting of a graphite and a silver gel.

16. The method as claimed in claim 15, wherein the third electrode layer is then dried after the conductive material is introduced and has conducted with the first conductive lines through the first conductive holes.

17. The method as claimed in claim 15, wherein the insulating layer is dried after the being printed on the first electrode layer.

18. The method as claimed in claim 15, wherein the third conductive lines are then dried after the conductive material is introduced and has conducted with the second conductive lines through the second conductive holes.
